(19) United States
(12) Patent Application Publication
(10) Pub. No.: US 2018/0026104 A1
(43) Pub. Date: Jan. 25, 2018

(54) P-TYPE OXIDE SEMICONDUCTOR, METHOD FOR FORMING P-TYPE OXIDE SEMICONDUCTOR, AND TRANSISTOR WITH THE P-TYPE OXIDE SEMICONDUCTOR

(71) Applicant: Electronics and Telecommunications Research Institute, Daejeon (KR)

(72) Inventors: Sung Haeng CHO, Cheongju-si (KR); Sooji NAM, Daejeon (KR); Chi-Sun HWANG, Daejeon (KR); Su Jae LEE, Daejeon (KR); Kyoung Ik CHO, Daejeon (KR); Jae-Eun PI, Daejeon (KR)

(73) Assignee: Electronics and Telecommunications Research Institute, Daejeon (KR)

(21) Appl. No.: 15/621,135

(22) Filed: Jun. 13, 2017

(30) Foreign Application Priority Data
Jul. 20, 2016 (KR) 10-2016-0092259
Nov. 18, 2016 (KR) 10-2016-0154389

(51) Int. Cl. H01L 29/24; H01L 21/02; H01L 29/786

(52) U.S. Cl. CPC H01L 29/24; H01L 29/7869; H01L 21/02565; H01L 21/0262; H01L 21/02623; H01L 21/02631

(57) ABSTRACT

Provided are a p-type oxide semiconductor, a method of forming the p-type oxide semiconductor, and a transistor with the p-type oxide semiconductor. The p-type oxide semiconductor includes an alkali metal and a tin oxide.

### CROSS-REFERENCE TO RELATED APPLICATIONS

This U.S. non-provisional patent application claims priority under 35 U.S.C. §119 of Korean Patent Application Nos. 10-2016-0092259, filed on Jul. 20, 2016, and 10-2016-0154389, filed on Nov. 18, 2016, the entire contents of which are hereby incorporated by reference.

### BACKGROUND OF THE INVENTION

The present invention disclosed herein relates to a p-type oxide semiconductor, a method of forming the p-type oxide semiconductor, and a transistor with the p-type oxide semiconductor, and more particularly, to a p-type oxide semiconductor including tin oxide with an alkali metal.

Generally, an oxide semiconductor has a band gap larger than that of silicon. Accordingly, in the case where an oxide semiconductor is used for an electronic device, it is possible to increase the transparency of the electronic device or its circuits. For example, the average transmittance to the visible light may be increased to about 50% or higher. In addition, it is possible to fabricate the electronic device at a relatively low temperature and moreover to fabricate the electronic device using a cheap substrate (e.g., of glass or plastic), which is applicable for a large area process.

As a result of active research on oxide semiconductors, many n-type oxide semiconductors with superior characteristics have been found. By contrast, to realize such superior characteristics in p-type oxide semiconductors, there is still a need for further study. In particular, tin oxide can exist in the form of SnO₂ (Sn⁴⁺) or SnO (Sn²⁺), and it has a crystalline structure and a band gap that are changed depending on its oxidation state. For example, SnO exhibits physical characteristics of p-type semiconductors, whereas SnO₂ exhibits physical characteristics of n-type semiconductors.

### SUMMARY

Some embodiments of the inventive concept provide a p-type oxide semiconductor with superior characteristics.

Some embodiments of the inventive concept provide a method of fabricating a p-type oxide semiconductor.

Some embodiments of the inventive concept provide a transistor with a p-type oxide semiconductor.

According to some embodiments of the inventive concept, a p-type oxide semiconductor may include an alkali metal and a tin oxide.

In some embodiments, the p-type oxide semiconductor may have a chemical formula of M₂ₓSn₃₋ₓO₃, where the M may be an alkali metal and 0.015075≦x≦1.285714. The p-type oxide semiconductor may satisfy the relation: 0.01≦[M]/([Sn]+[M])≦0.60. [M] may represent a content (atomic %) of the M and [Sn] may represent a content (atomic %) of Sn.

In certain embodiments, the p-type oxide semiconductor may satisfy the relation: 0.05≦[M]/([Sn]+[M])≦0.30. In particular, the p-type oxide semiconductor may satisfy the relation: 0.10≦[M]/([Sn]+[M])≦0.20. The M may be one selected from the group consisting of Li, Na, K, Rb, Cs, and Fr.

According to some embodiments of the inventive concept, a method of forming a p-type oxide semiconductor is provided. The method may include reacting an alkali metal compound with a tin compound to form a reaction product, forming a layer, which is formed of the reaction product, on a substrate, and thermally treating the layer to form a p-type oxide semiconductor.

In some embodiments, the forming of the layer may be performed by using one of sputtering deposition, plasma enhanced chemical vapor deposition (PECVD), metal organic chemical vapor deposition (MOCVD), atomic layer deposition (ALD), pulsed laser deposition (PLD), Sol-Gel Method, spin coating, spray coating, dip coating, inkjet coating, and electro-hydro-dynamic (EHD) coating methods.

In the method, the p-type oxide semiconductor may be formed to have the above chemical formula.

In some embodiments, the layer may be formed to have a thickness ranging from about 5 nm to about 1000 nm.

According to some embodiments of the inventive concept, a transistor may include a substrate, a gate electrode on the substrate, an insulation layer covering the gate electrode, source/drain electrodes on the insulation layer, and a semiconductor layer formed on the insulation layer and electrically connected to the source/drain electrodes. The semiconductor layer may include a p-type oxide semiconductor having a composition of the above chemical formula.

In some embodiments, the semiconductor layer may be provided on the insulation layer exposed between the source/drain electrodes.

In some embodiments, the transistor may further comprise an etch-resistant layer formed on the semiconductor layer. The source/drain electrodes may be formed on the semiconductor layer, and the etch-resistant may be provided between the source/drain electrodes.

In some embodiments, the transistor may further comprise a protective insulation layer covering the source/drain electrodes and the semiconductor layer.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 is a flowchart showing a method of fabricating a p-type oxide semiconductor, according to some embodiments of the inventive concept;

FIG. 2 is a sectional view illustrating a p-type oxide semiconductor layer formed by the fabrication method of FIG. 1;

FIGS. 3A to 3C are graphs showing X-ray photoelectron spectroscopy (XPS) spectra obtained from the p-type oxide semiconductor layer of FIG. 2;

FIG. 4 is a graph showing X-ray diffraction (XRD) spectra obtained from the p-type oxide semiconductor layer of FIG. 2;

FIG. 5 is a graph showing transmittance of the p-type oxide semiconductor layer of FIG. 2 with respect to a ratio (%) of [K]/([Sn]+[K]);

FIG. 6 is a graph showing optical bandgaps of the p-type oxide semiconductor layer of FIG. 2 with respect to a ratio (%) of [K]/([Sn]+[K]);

FIG. 7 is a sectional view illustrating a thin-film transistor, in which a p-type oxide semiconductor layer according to some embodiments of the inventive concept is provided;

FIGS. 8A to 8F are graphs showing electrical characteristics of the thin-film transistor of FIG. 7 at different ratios (%) of [K]/([Sn]+[K]);

FIG. 9 is a sectional view of a thin-film transistor including a p-type oxide semiconductor according to some embodiments of the inventive concept; and

FIG. 10 is a sectional view of a thin-film transistor including a p-type oxide semiconductor according to some embodiments of the inventive concept.

### DETAILED DESCRIPTION

The inventive concept will now be described more fully hereinafter with reference to the accompanying drawings, in which exemplary embodiments of the inventive concept are shown. The advantages and features of the inventive concept and methods of achieving them will be apparent from the following exemplary embodiments that will be described in more detail with reference to the accompanying drawings. It should be noted, however, that the inventive concept is not limited to the following exemplary embodiments, and may be implemented in various forms. Accordingly, the exemplary embodiments are provided only to disclose the inventive concept and let those skilled in the art know the category of the inventive concept. In the drawings, embodiments of the inventive concept are not limited to the specific examples provided herein and are exaggerated for clarity.

The terminology used herein is for the purpose of describing particular embodiments only and is not intended to limit the invention. As used herein, the singular terms “a,” “an” and “the” are intended to include the plural forms as well, unless the context clearly indicates otherwise. As used herein, the term “and/or” includes any and all combinations of one or more of the associated listed items. It will be understood that when an element is referred to as being “connected” or “coupled” to another element, it may be directly connected or coupled to the other element or intervening elements may be present.

Similarly, it will be understood that when an element such as a layer, region or substrate is referred to as being “on” another element, it can be directly on the other element or intervening elements may be present. In contrast, the term “directly” means that there are no intervening elements. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Additionally, the embodiment in the detailed description will be described with sectional views as ideal exemplary views of the inventive concept. Accordingly, shapes of the exemplary views may be modified according to manufacturing techniques and/or allowable errors. Therefore, the embodiments of the inventive concept are not limited to the specific shape illustrated in the exemplary views, but may include other shapes that may be created according to manufacturing processes. Areas exemplified in the drawings have general properties, and are used to illustrate specific shapes of elements. Thus, this should not be construed as limited to the scope of the inventive concept.

Moreover, exemplary embodiments are described herein with reference to cross-sectional illustrations and/or plane illustrations that are idealized exemplary illustrations. Accordingly, variations from the shapes of the illustrations as a result, for example, of manufacturing techniques and/or tolerances, are to be expected. Thus, exemplary embodiments should not be construed as limited to the shapes of regions illustrated herein but are to include deviations in shapes that result, for example, from manufacturing. For example, an etching region illustrated as a rectangle will, typically, have rounded or curved features. Thus, the regions illustrated in the drawings are schematic in nature and their shapes are not intended to illustrate the actual shape of a region of a device and are not intended to limit the scope of example embodiments.

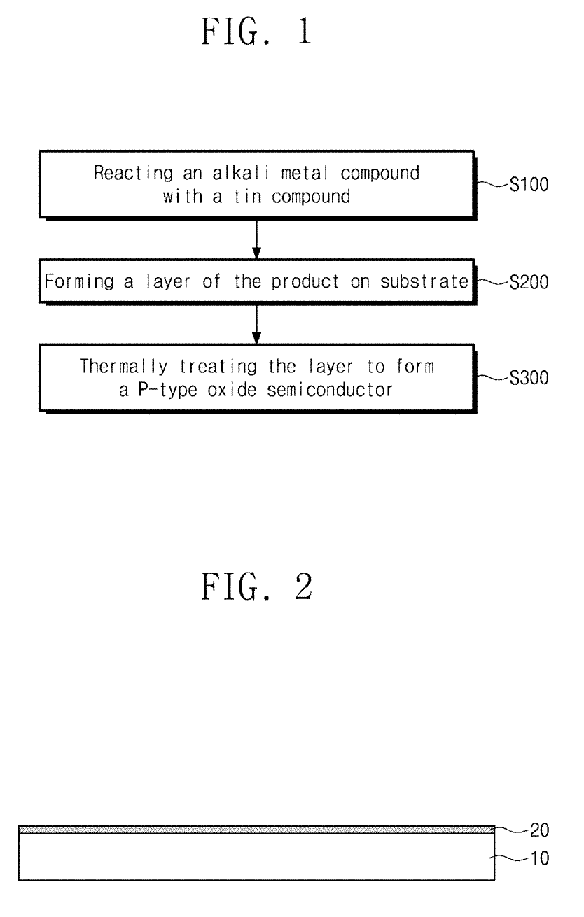

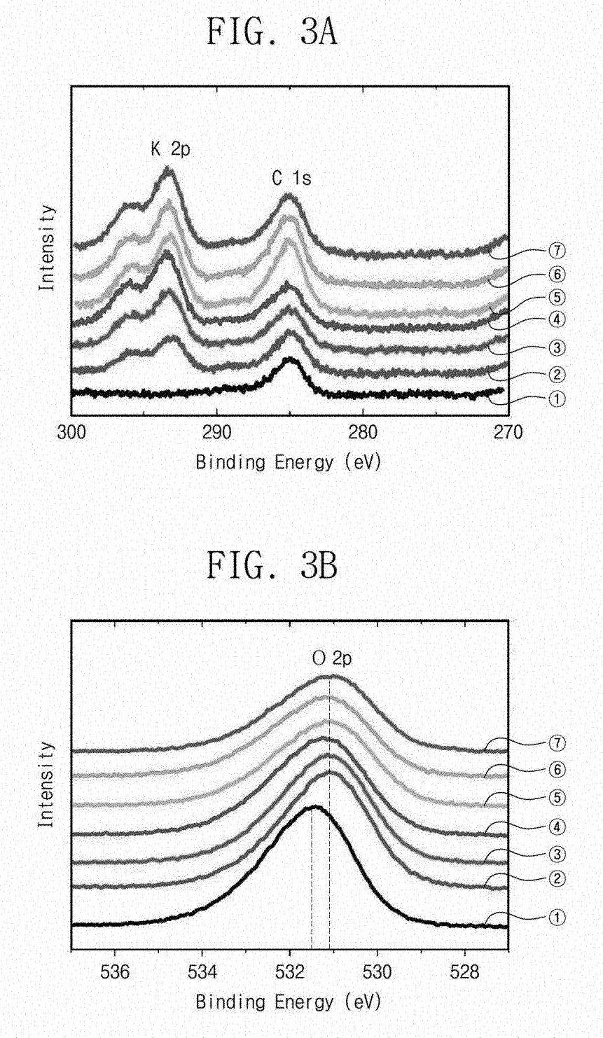

FIG. 1 is a flowchart showing a method of fabricating a p-type oxide semiconductor, according to some embodiments of the inventive concept. FIG. 2 is a sectional view illustrating a p-type oxide semiconductor layer formed by the fabrication method of FIG. 1.

Referring to FIGS. 1 and 2, an alkali metal compound is reacted with a tin compound (S100). In the case where the alkali metal compound and the tin compound is placed in a solvent, solution containing an alkali metal and tin is formed. For example, the alkali metal compound may be KCl, the tin compound may be SnCl₂, and the solvent may be 2-methoxy ethanol. A KSnO solution may be formed by reaction between KCl and SnCl₂ in 2-methoxy ethanol at room temperature.

As a result of the reaction, a layer may be formed on a substrate 10 (S200). The substrate 10 may be, but is not limited to, a silicon substrate. The layer may be formed using one of sputtering, plasma enhanced chemical vapor deposition (PECVD), metal organic chemical vapor deposition (MOCVD), atomic layer deposition (ALD), pulsed laser deposition (PLD), spin coating, spray coating, dip coating, inkjet coating, and electro-hydro-dynamic (EHD) coating methods. As an example, a spin coating method may be used to form the layer on the substrate 10. The layer may be formed to have a thickness ranging from about 5 nm to about 1000 nm. In some embodiments, the layer may have a thickness ranging from about 49 nm to about 100 nm.

Thereafter, the layer is thermally treated to form a p-type oxide semiconductor layer 20 (S300). As a concrete example, the layer may be irradiated by a UV light and then thermally treated. In certain embodiments, a thermal treatment process may be performed on the substrate 10 with the layer at a temperature ranging from about 200° C. to about 500° C. As a result of the thermal treatment process, the solvent contained in the layer may be decomposed and evaporated, and thus, the layer may be hardened.

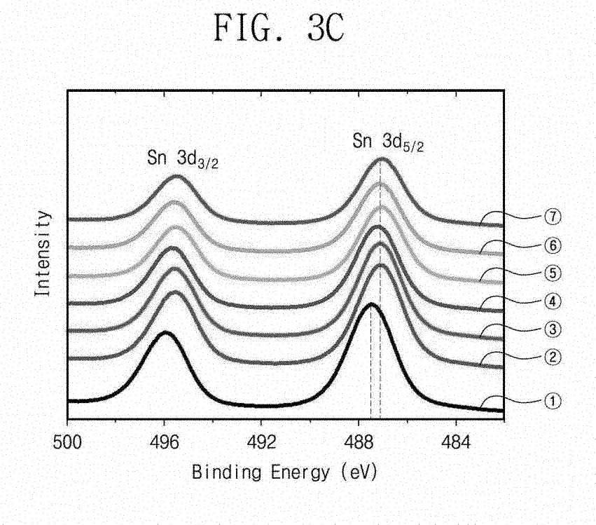

Hereinafter, the characteristics of the p-type oxide semiconductor layer 20 formed by the method will be described with reference to FIGS. 3A to 6. The p-type oxide semiconductor according to some embodiments of the inventive concept contains an alkali metal, but for the sake of simplicity, the description that follows will refer to examples in which potassium (K) is used as one of the alkali metals for the p-type oxide semiconductor.

FIGS. 3A to 3C are graphs showing X-ray photoelectron spectroscopy (XPS) spectra obtained from the p-type oxide semiconductor layer 20 of FIG. 2. In detail, FIGS. 3A to 3C show XPS spectra of K 2p, O 2p, and Sn 3d_{5/2} of the p-type oxide semiconductor layer measured at different ratios (%) of [K]/([Sn]+[K]). In FIGS. 3A to 3C, reference numbers \textcircled{1} to \textcircled{7} represent XRD spectra obtained from samples, in which the ratios (%) of [K]/([Sn]+[K]) are 0% (No potassium), 5%, 10%, 15%, 20%, 25%, and 30%, respectively. In the present specification, [K] and [Sn] represents contents (in atomic %) of potassium (K) and tin (Sn).

Referring to FIG. 3A, peaks of K 2p shows that the higher the ratio of [K]/([Sn]+[K]), the higher the potassium content in the p-type oxide semiconductor layer 20. That is, FIG. 3A shows that as the content of K in a solution increases, an amount of K, which is reacted with tin in the p-type oxide semiconductor layer 20, also increases. In FIG. 3A, peaks of C is were used as reference for adjusting a binding energy in the XPS spectrum.

Referring to FIG. 3B, as the ratio of [K]/([Sn]+[K]) increased, the electron binding energy of O 2p peaks were lowered. For example, the potassium-free sample of \textcircled{1} means O 2p orbital (e.g., corresponding to Sn⁴⁺) having a binding energy of about 531.5 eV, but other potassium-containing samples of \textcircled{2} to \textcircled{7} show that the addition of potassium led to a change to O 2p orbital (e.g., corresponding to Sn²⁺) having a binding energy of about 531.1 eV.

Referring to FIG. 3C, as the ratio of [K]/([Sn]+[K]) increased, the electron binding energy of Sn 3d_{5/2} peaks were lowered. For example, for the potassium-free sample of \textcircled{1}, the binding energy was about 487.5 eV, but for other potassium-containing samples of \textcircled{2} to \textcircled{7}, the binding energy was changed to about 487.1 eV. These results confirm that the oxidation number is changed from Sn⁴⁺ to Sn²⁺.

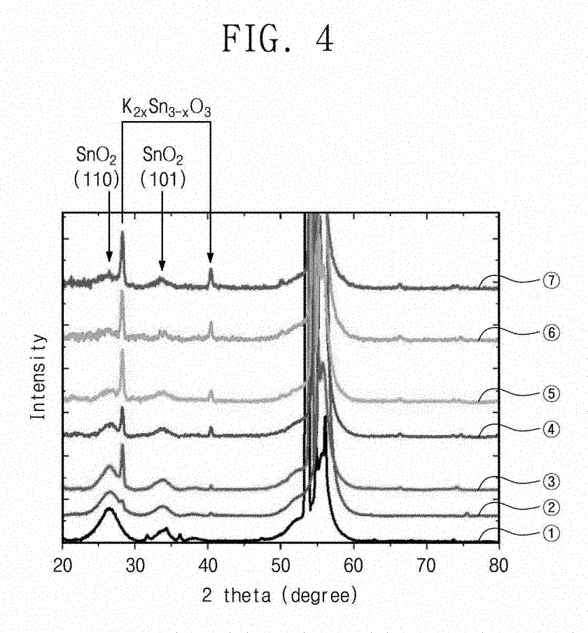

FIG. 4 is a graph showing X-ray diffraction (XRD) spectra obtained from the p-type oxide semiconductor layer of FIG. 2. Data shown in FIG. 4 were obtained at various ratios (%) of [K]/([Sn]+[K]), and in detail, reference numbers \textcircled{1} to \textcircled{7} represent XRD spectra obtained from samples, in which the ratios (%) of [K]/([Sn]+[K]) are 0% (No potassium), 5%, 10%, 15%, 20%, 25%, and 30%, respectively.

As shown in FIG. 4, for the potassium-free sample of \textcircled{1}, (110) and (101) peaks of SnO₂ crystal were mainly observed. However, FIG. 4 also shows that by increasing an amount of the added K, it is possible to increase intensities of peaks of K_{2X}Sn_{3-X}O₃ crystal, which corresponds to Sn⁺², at 28.27 degree and 40.42 degree. That is, a p-type oxide semiconductor according to the inventive concept may be defined as the following chemical formula 1.

M₂ₓSn₃₋ₓO₃. <Chemical formula 1>

Here, the M may be an alkali metal and 0.015075≦x≦1.285714. The p-type oxide semiconductor may satisfy the relation: 0.01≦[M]/([Sn]+[M])≦0.60. [M] may represent a content (in atomic %) of the M and [Sn] may represent a content (in atomic %) of Sn. Preferably, the p-type oxide semiconductor may satisfy the relation: 0.05≦[M]/([Sn]+[M])≦0.30. More preferably, the p-type oxide semiconductor may satisfy the relation: 0.10≦[M]/([Sn]+[M])≦0.20. The M may be one selected from the group consisting of Li, Na, K, Rb, Cs, and Fr.

The following table 1 shows the results that were obtained by measuring Hall effect in the p-type oxide semiconductor layer 20 of FIG. 2 at different ratios (%) of [K]/([Sn]+[K]). In detail, the measurement were performed at ratios (%) of [K]/([Sn]+[K]) of 0% (No potassium), 5%, 10%, 15%, 20%, 25%, and 30%, respectively. In the case where potassium is not added, the resulting p-type oxide semiconductor layer exhibits electrical characteristics similar to those of an n-type semiconductor, in which electrons are used as a charge carrier. By contrast, in the case when the potassium is added, the resulting p-type oxide semiconductor layer exhibits electrical characteristics similar to those of a p-type semiconductor, in which holes are used as a charge carrier.

TABLE 1

| | Hall effect measurement | |
|---|---|---|
| Ratio (%) of [K]/([Sn] + [K]) | carrier conc. (cm⁻³) | mobility (cm²/Vs) |
| 0% | −1.59 × 10¹⁶ | 12.2 |
| 5% | +2.78 × 10¹⁴ | 36.6 |
| 10% | +9.07 × 10¹⁴ | 6.04 |
| 15% | +1.01 × 10¹⁴ | 33.7 |
| 20% | +1.26 × 10¹⁴ | 36.2 |
| 25% | +3.42 × 10¹³ | 153 |
| 30% | +2.34 × 10¹³ | 154 |

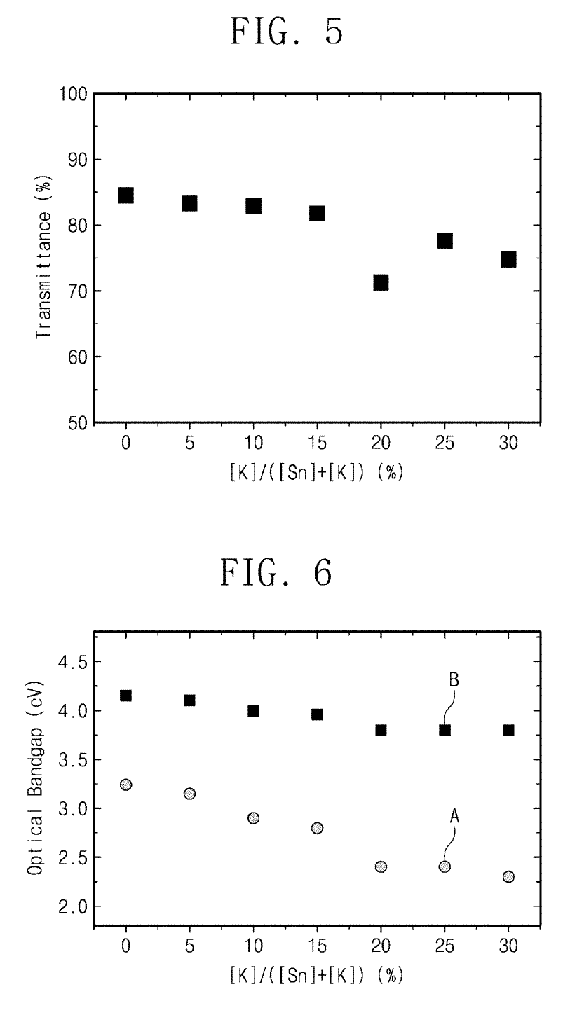

FIG. 5 is a graph showing transmittance of the p-type oxide semiconductor layers 20 of FIG. 2 with respect to a ratio (%) of [K]/([Sn]+[K]). Referring to FIG. 5, in visible wavelength ranging from about 380 nm and 770 nm, the p-type oxide semiconductor layers 20 had average transmittance of about 75%-84%. Here, the p-type oxide semiconductor layers 20 had thicknesses ranging from about 49 nm to about 100 nm.

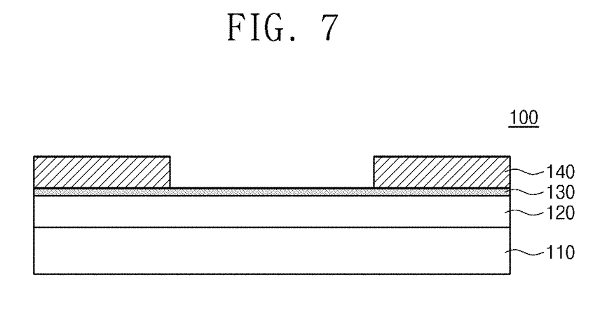

FIG. 6 is a graph showing optical bandgaps of the p-type oxide semiconductor layers 20 of FIG. 2 with respect to a ratio (%) of [K]/([Sn]+[K]). In FIG. 6, A and B represent an indirect-allowed optical bandgap and a direct-allowed optical bandgap, respectively. FIG. 6 shows that an increase in the content of K led to a lowering in optical bandgaps of the p-type oxide semiconductor layer, and this result confirms that, as previously described with reference to FIGS. 3A to 4, an increase of potassium content leads to a change in chemical composition from SnO₂ to SnO.

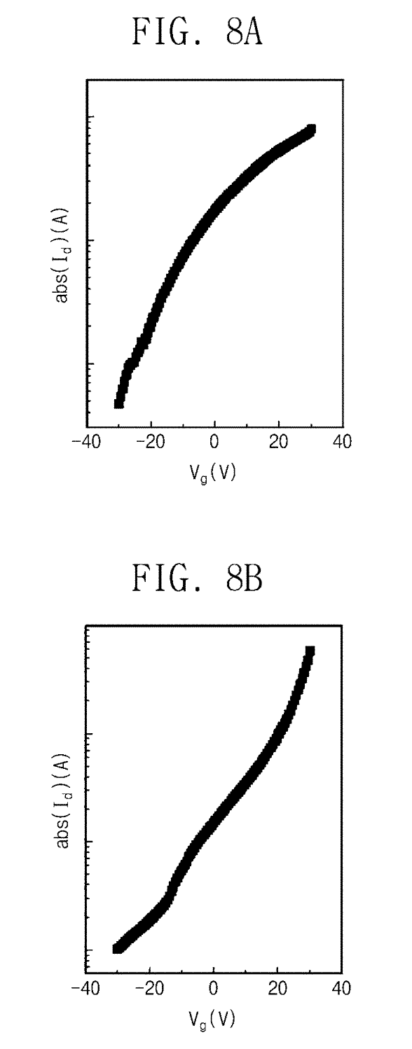

FIG. 7 is a sectional view illustrating a transistor 100, in which a p-type oxide semiconductor layer according to some embodiments of the inventive concept is provided. The transistor 100 may be a thin-film transistor for a test. Referring to FIG. 7, the thin-film transistor 100 may include a substrate 110, an insulation layer 120, a semiconductor layer 130, and source/drain electrodes 140.

The substrate 110 may be transparent. For example, the substrate 110 may be a glass substrate or a transparent plastic substrate. The insulation layer 120 may be provided on the substrate 110. The insulation layer 120 may be transparent. For example, the insulation layer 120 may be formed of or include one of aluminum oxide, silicon oxide, silicon nitride, and silicon oxynitride. The semiconductor layer 130 may be provided on the insulation layer 120. The semiconductor layer 130 may be formed to have the same features as the p-type oxide semiconductor layer 20 described with reference to FIG. 2. The semiconductor layer 130 may serve a channel region of the thin-film transistor 100. In the case where the thin-film transistor 100 is turned on, the source/drain electrodes 140 may be electrically connected to each other via the semiconductor layer 130. The source/drain electrodes 140 may be provided on the semiconductor layer 130. The source/drain electrodes 140 may be in direct contact with the semiconductor layer 130. The source/drain electrodes 140 and the semiconductor layer 130 may form an ohmic contact.

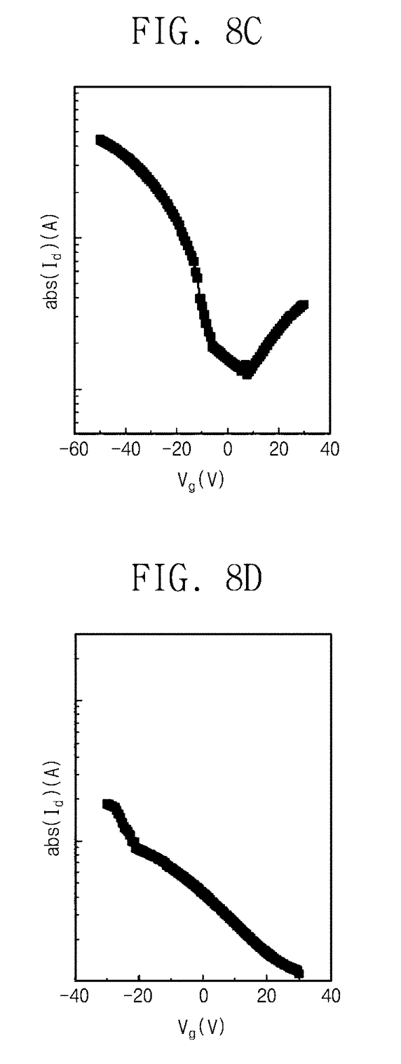

FIGS. 8A to 8F are graphs showing transport and output characteristics of the thin-film transistor of FIG. 7 at different ratios (%) of [K]/([Sn]+[K]). The graphs of FIGS. 8A to 8F were measured at ratios (%) of [K]/([Sn]+[K]) of 0% (No potassium), 5%, 10%, 15%, 20%, 25%, and 30%, respectively. Referring to FIGS. 8A and 8B, as a gate voltage Vg applied to the thin-film transistor 100 was increased, the transport and output characteristics of the thin-film transistor 100 were improved, and the semiconductor layer 130 exhibited electrical characteristics similar to those of an n-type semiconductor. By contrast, as shown in FIGS. 8C to 8F, as the gate voltage Vg applied to the thin-film transistor 100 was lowered, the transport and output characteristics of the thin-film transistor 100 were improved, and the semiconductor layer 130 exhibited electrical characteristics similar to those of a p-type semiconductor.

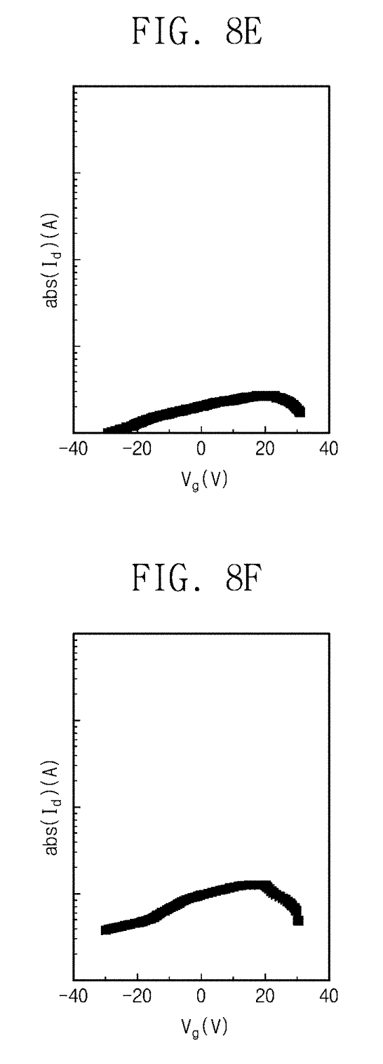

FIG. 9 is a sectional view of a thin-film transistor 100a including a p-type oxide semiconductor according to some embodiments of the inventive concept. In the following description, an element, which is substantially the same as that of the thin-film transistor 100 previously described with reference to FIG. 7, may be identified by the same reference number without repeating an overlapping description thereof. Referring to FIG. 9, the thin-film transistor 100a may include a substrate 110, a gate electrode 115, an insulation layer 120, a semiconductor layer 130, source/drain electrodes 140, and a protective insulation layer 150.

The gate electrode 115 may be provided on the substrate 110. The gate electrode 115 may cover a portion of an upper surface of the substrate 110. The gate electrode 115 may be configured to prevent light from passing therethrough. The gate electrode 115 may be formed of a metal. For example, the gate electrode 115 may be formed of or include at least one of tungsten, aluminum, copper, platinum, gold, silver, titanium, or molybdenum.

The insulation layer 120 may be provided to cover the substrate 110 and the gate electrode 115. When viewed in a plan view, a portion of the semiconductor layer 130 may be overlapped with the gate electrode 115, and the remaining portion of the semiconductor layer 130 may be provided to partially cover the source/drain electrodes 140. That is, the semiconductor layer 130 may be provided on a portion of the insulation layer 120 exposed between the source/drain electrodes 140. The semiconductor layer 130 may be electrically disconnected from the gate electrode 115 by the insulation layer 120.

The protective insulation layer 150 may be provided to cover the semiconductor layer 130 and the source/drain electrodes 140. The protective insulation layer 150 may be formed of or include at least one of aluminum oxide, silicon oxide, silicon nitride, or silicon oxynitride.

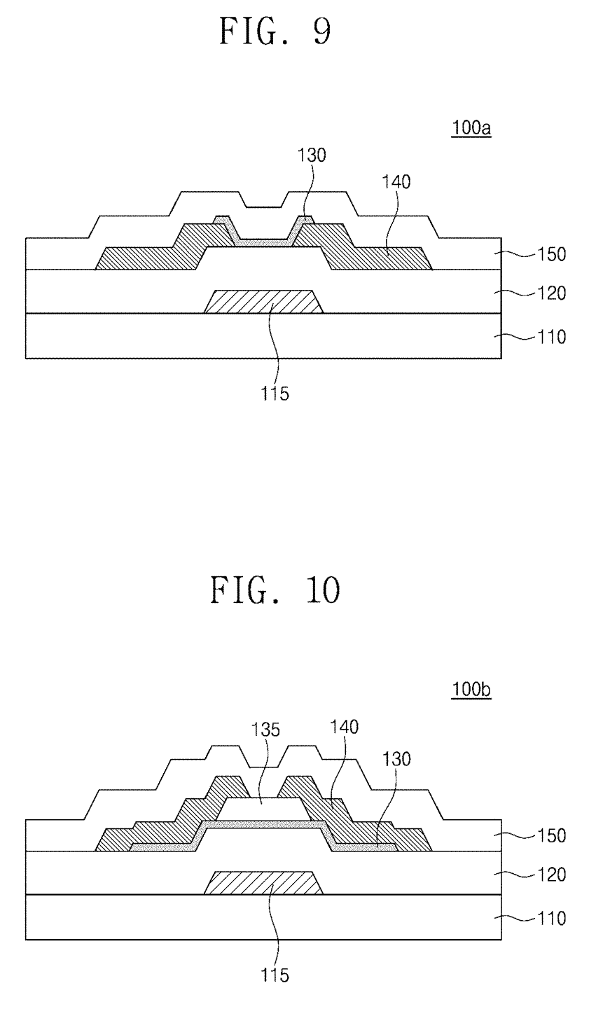

FIG. 10 is a sectional view of a thin-film transistor 100b including a p-type oxide semiconductor according to some embodiments of the inventive concept. In the following description, an element, which is substantially the same as that of the thin-film transistor 100a previously described with reference to FIG. 9, may be identified by a similar or identical reference number without repeating an overlapping description thereof. As shown in FIG. 10, the thin-film transistor 100b may further include an etch-resistant layer 135.

The semiconductor layer 130 may be formed on the insulation layer 120. The etch-resistant layer 135 may be provided on the semiconductor layer 130. As an example, a portion of the semiconductor layer 130 may be covered with the etch-resistant layer 135 and the other portion of the semiconductor layer 130 may be covered with the source/drain electrodes 140. The etch-resistant layer 135 may be overlapped with the gate electrode 115, when viewed in a plan view.

According to some embodiments of the inventive concept, it may be possible to provide a novel p-type oxide semiconductor with superior characteristics. In addition, the p-type oxide semiconductor may be formed using a solution process (e.g., a spin coating process), and thus, it may be possible to cost-effectively form a p-type oxide semiconductor layer at a low temperature.

The p-type oxide semiconductor according to some embodiments of the inventive concept may be applied to various transparent electronic products, such as a thin-film transistor (TFT), a large-size electronic device like a display or an image sensor, a pn-junction diode, a pn-junction light emitting diode, a transparent solar cell, a transparent sensor, and a precision diagnostic imaging device

The thin-film transistors 100, 100a, 100b of FIGS. 7, 9, and 10 were described as some examples according to the inventive concept, but the inventive concept is not limited to the examples of FIGS. 7, 9, and 10.

Some embodiments of the inventive concept provide a p-type oxide semiconductor having not only novel chemical composition but also superior characteristics. In addition, the p-type oxide semiconductor may be formed using a solution process (e.g., a spin coating process), and thus, it may be possible to cost-effectively form a p-type oxide semiconductor layer at a low temperature.

While example embodiments of the inventive concepts have been particularly shown and described, it will be understood by one of ordinary skill in the art that variations in form and detail may be made therein without departing from the spirit and scope of the attached claims.

What is claimed is:

1. A p-type oxide semiconductor comprising:
an alkali metal; and
a tin oxide.

2. The semiconductor of claim 1 having a chemical formula of M₂ₓSn₃₋ₓO₃,
wherein the M is an alkali metal, 0.015075≦x≦1.285714,
0.01≦[M]/([Sn]+[M])≦0.60,
[M] represents a content (atomic %) of the M, and
[Sn] represents a content (atomic %) of Sn.

3. The semiconductor of claim 2, wherein 0.05≦[M]/([Sn]+[M])≦0.30.

4. The semiconductor of claim 3, wherein 0.10≦[M]/([Sn]+[M])≦0.20.

5. A method of forming a p-type oxide semiconductor, comprising:
reacting an alkali metal compound with a tin compound to form a reaction product;
forming a layer, which is formed of the reaction product, on a substrate; and
thermally treating the layer to form a p-type oxide semiconductor.

6. The method of claim 5, wherein the forming of the layer is performed by using one of sputtering, plasma enhanced chemical vapor deposition (PECVD), metal organic chemical vapor deposition (MOCVD), atomic layer deposition (ALD),
pulsed laser deposition (PLD), Sol-Gel methods, spin coating, spray coating, dip coating, inkjet coating, and electro-hydro-dynamic (EHD) coating methods.

7. The method of claim 5, wherein the p-type oxide semiconductor has a chemical formula of M₂ₓSn₃₋ₓO₃,
wherein the M is an alkali metal, 0.015075≦x≦1.285714,
0.01≦[M]/([Sn]+[M])≦0.60,
[M] represents a content (atomic %) of the M, and
[Sn] represents a content (atomic %) of Sn.

8. The method of claim 7, wherein 0.05≦[M]/([Sn]+[M])≦0.30.

9. The method of claim 8, wherein 0.10≦[M]/([Sn]+[M])≦0.20.

10. The method of claim 5, wherein the layer is formed to have a thickness ranging from about 5 nm to about 1000 nm.

11. A transistor comprising:
a substrate;
a gate electrode on the substrate;
an insulation layer covering the gate electrode;
source/drain electrodes on the insulation layer; and
a semiconductor layer formed on the insulation layer and electrically connected to the source/drain electrodes,
wherein the semiconductor layer comprises a p-type oxide semiconductor having a composition of a chemical formula of M₂ₓSn₃₋ₓO₃,
wherein the M is an alkali metal, 0.015075≦x≦1.285714,
0.01≦[M]/([Sn]+[M])≦0.6,
[M] represents a content (atomic %) of the M, and
[Sn] represents a content (atomic %) of Sn.

12. The transistor of claim 11, wherein 0.05≦[M]/([Sn]+[M])≦0.30.

13. The transistor of claim 12, wherein 0.10≦[M]/([Sn]+[M])≦0.20.

14. The transistor of claim 11, wherein the semiconductor layer is provided on the insulation layer exposed between the source/drain electrodes.

15. The transistor of claim 11, further comprising an etch-resistant layer formed on the semiconductor layer,
wherein the source/drain electrodes are formed on the semiconductor layer, and the etch-resistant is provided between the source/drain electrodes.

16. The transistor of claim 11, further comprising a protective insulation layer covering the source/drain electrodes and the semiconductor layer.
